(19) United States
(12) Patent Application Publication
(10) Pub. No.: US 2011/0211357 A1
(43) Pub. Date: Sep. 1, 2011

(54) METHOD FOR PRODUCING A FLEXIBLE LIGHT STRIP

(75) Inventors: Thomas Preuschl, Sinzing (DE); Steffen Strauss, Regensburg (DE)

(73) Assignee: OSRAM GESELLSCHAFT MIT BESCHRAENKTER HAFTUNG, Muenchen (DE)

(21) Appl. No.: 13/127,054

(22) PCT Filed: Nov. 2, 2009
(86) PCT No.: PCT/EP09/64469

§ 371 Date: May 2, 2011

(30) Foreign Application Priority Data
Nov. 3, 2008 (DE) 102008054288.1

(51) Int. Cl. F21V 19/02; H05K 3/30

(52) U.S. Cl. 362/418; 29/829

(57) ABSTRACT

A method for producing a flexible light strip having a substrate designed for bending and provided for fitting with light sources, is provided. The method may include singularizing the light strip from an endless intermediate product; and the endless intermediate product having at least one fiberglass composite layer.

The invention relates to a method for producing a flexible light strip and to a flexible light device including a substrate designed for bending which is provided for fitting with light sources.

Strip-shaped flexible LED carriers are known. For example, under the trade name “LINEARlight Flex”, flexible separable LED modules with a self-adhesive back are supplied by OSRAM, Germany. The substrate thereof is manufactured based on polyamide. A module consists of 10 LEDs with a length of 140 mm. The total length on a roll comes to 8.40 m.

Single-layer or multilayer thin flexible printed circuit boards which use polyamide films in the substrate are also known. Polyamide provided for this intended application is marketed, for example, by DuPont under the trade name “Kapton”. In flexible printed circuit boards, multiple layer pairs, each comprising a polyamide film and an epoxy resin layer stacked on top of one another, are frequently used. A copper layer, the usual copper thickness (thickness) of which is approximately 18 μm, is frequently also present. The copper layer increases the flexibility of the substrate. Greater copper thicknesses of up to 35 μm are considered suitable for practical use. A copper thickness of 70 μm is considered to be the maximum useful thickness, as copper thicknesses over and above this make the flexible printed circuit board so rigid that it can usually no longer be called flexible. Typical substrate thicknesses for single-layer PI layers lie in the range between 100 μm and 150 μm, a thickness of a single layer typically lying between 25 μm and 35 μm. The so-called flexible circuits composed of flexible printed circuit boards are more expensive, but can be used in a space-saving manner by being folded into the most compact structures. Flexible connections for continuous loading, e.g. in inkjet printers, are frequently also fashioned as a polyamide-film printed circuit board. Where, however, an area in the printed circuit board is needed that is not permanently flexible, e.g. in order to enable assembly under confined installation conditions, there is the approach of tapering a layer stack of a printed circuit board consisting, apart from a few layers, of multiple prepregs, by milling or of tapering pre-stamped prepregs with recessed areas. The tapered area is typically furnished with a permanently flexible lacquer layer and can then be folded few times. As an alternative material to polyamide, polyester (in particular polyethylene terephthalate, PET) is known, polyamide being considered the higher-quality solution. In terms of thermal stability, dielectric strength and dimensional stability, polyamide clearly outperforms polyester.

Flexible light strips are also marketed, for example, by the company “electronic service willms” in Germany under the trade name “LED-Flex-Strip HV”. These light strips are manufactured using a panel method and do not exceed 60 cm in length. To manufacture a light strip of more than 60 cm in length, the individual light strips have to be connected to one another and electrically contacted. The LED-Flex-Strips HV have a minimum bending radius of approximately 25 mm.

The company Lamitec-Dialektra GmbH supplies under the trade name “15193-Flex20 Laminate” a flexible FR4 system with high-ductility (HD) copper for use with rigid-flexible printed circuit boards for so-called “bending to install”. FR4 layers include a composite made of fiberglass cloth and epoxy resin. The minimum bending radius lies at 4 mm. Processability for the usual standard FR4 processes is guaranteed. The 15193-Flex 20 laminates are obtainable as sheets or in blank cuts including an FR4 layer with copper cladding on one or both sides. Standard copper thicknesses are 18 μm, 35 μm and 70 μm. The thickness of an FR4 layer is 75 μm or 125 μm. The number of bending cycles depends on the bending radius and is between 10 and 100 for a bending radius of 4 mm, with a higher laminate strength allowing a greater number of bendings.

The object of the present invention is to provide a flexible light device which is particularly environmentally friendly and reliable, in particular for greater lengths.

This object is achieved in a method for producing a light strip and a flexible light device as claimed in the respective independent claim. Preferred embodiments can be inferred in particular from the dependent claims.

The method is configured for producing a flexible light strip including a substrate designed for bending and provided for fitting with light sources. The method includes a step of singularizing the light strip from an endless intermediate product. An “endless intermediate product” is understood to mean an intermediate product whose length is not relevant in practice to the production of a light strip because it is very much longer than the length of a typical light strip. The endless intermediate product includes at least one fiberglass composite layer.

The use of a fiberglass composite material has the advantages that production of the substrate can be carried out at lower temperatures and thus in a more energy-saving manner than using polyamide or polyester. Also, a fiberglass composite material is more readily recyclable. Furthermore, the absorption of water, which can be up to 3% in the case of polyamide, is low for fiberglass composite materials, which results in better protection against corrosion or degradation than in the case of polyamide. Reliability is in this way increased. Reliability is further increased through the use of an endless intermediate product, particularly in a so-called “roll-to-roll” method, since the limited lengths of max. 60 cm which arise in a panel production method can be avoided hereby. To produce a light strip of more than 60 cm in length, the individual light strips have to be connected to one another and electrically contacted. However, the endless intermediate product makes it possible for a jointless light strip of more than 60 cm in length to be produced at no extra cost, which enables a smaller bending radius, minimizes production faults and is more cost-effective.

The endless intermediate product is preferably supplied in the form of a roll (“endless roll”) prior to its further processing into a flexible light strip device. Such a roll is easy to transport and ready for use without special machining.

Light-emitting diodes in particular are preferred as light sources, as these combine high light intensity with comparatively low heat generation and, in addition, are compact and robust. Furthermore, light-emitting diodes can easily be fitted automatically.

In particular, a method is preferred in which, during the step of singularizing, multiple light strips can be singularized from the endless intermediate product. The endless intermediate product includes in particular across its width multiple areas which are assigned to different substrates or light strips to be singularized. Consequently, the endless intermediate product preferably includes multiple adjacent singularizable substrates or light strips (pre-fitted substrates). In this way, production can be achieved with high throughput and low production costs.

A method may be preferred in which the at least one light strip is singularized from the endless intermediate product pre-fitted. This has the advantage that fitting can be carried out on a large scale on the endless intermediate product, which enables particularly streamlined production.

A method may, however, be preferred in which the at least one light strip is singularized bare from the endless intermediate product, i.e. at least one substrate is singularized from the endless intermediate product. This can then be fitted to form a light strip later.

The endless intermediate product may have an unpatterned copper cladding which is clad only during the processing operation. For ease of singularization and cost-effective division of labor, it is, however, preferable if the endless intermediate product has at least one patterned copper cladding.

For ease of preparation of the light strip, it is preferable if the step of singularizing the light strip is followed by a step of detaching at least one light strip (according to a predefined length).

For particular ease of use in great lengths or areas, it is preferable if a light strip has a length of at least 1 m (is detached with a length of at least 1 m), in particular between 1 m and 20 m. In this way, the assembly cost can be reduced substantially while the conductive properties remain non-critical. Of course, greater lengths are also possible, optionally using stronger power sources.

A method is also preferred in which the endless intermediate product has a width of between 100 mm and 400 mm.

A method according to one of the preceding claims in which a light strip has a strip width of between 5 mm and 40 mm is also.

A flexible light device is produced according to the above method.

The flexible light device, particularly if it is produced according to the above method, is equipped with a substrate designed for bending which is provided for fitting with light sources. “Designed for bending” here means that the item concerned is intended and configured for being bent. In contrast to light devices according to the prior art, the substrate is produced from a fiberglass composite. The use of a fiberglass composite material has the advantages that production of the substrate can be carried out at lower temperatures and thus in a more energy-saving manner than for polyamide or polyester. Also, a fiberglass composite material is more readily recyclable. Furthermore, the absorption of water, which can be up to 3% in the case of polyamide, is low for fiberglass composite materials, which provides better protection against corrosion or degradation than is the case with polyamide. Reliability is in this way increased. The light device is also fashioned jointlessly, which can be achieved, for example, through the use of an ‘endless’ production process, e.g. a “roll-to-roll” process.

A flexible light device is preferred in which the fiberglass composite of the fiberglass composite layer is a fiberglass resin composite, for low-cost production in particular a fiberglass epoxy-resin composite. However, to increase thermal stability, it can also be advantageous to use BT resins or PI resins.

To reduce the proportion of brittle material in the at least one fiberglass resin composite layer, it is in particular preferred if the fiberglass composite is a fiberglass resin composite with a fiberglass proportion of less than 50% and more than 30%, in particular with a fiberglass proportion of between 30% and 45%, specifically of 35%.

A flexible light device is preferred which is fitted with at least one light-emitting diode as a light source, as in this way a particularly light-intensive light device is produced which generates comparatively little heat. However, other light sources can also be used such as other semiconductor light-emitting elements (e.g. laser diodes) or other lamp types.

For improved shape retention, a substrate is preferred which includes at least one layer made of ductile material, preferably metal such as aluminum or (preferably) copper. The metal layer can be located in the fiberglass composite layer. It is, however, preferred if the at least one fiberglass composite layer is clad with at least one copper layer, as this firstly enables a single-layer fiberglass composite layer and secondly allows ease of production. Furthermore, the copper layer can then easily be patterned, e.g. etched, to produce conductor tracks, contact areas, etc. The remaining copper surface increases further the shape-retaining characteristic, in comparison to an unclad fiberglass composite. The aim here will be to preserve the greatest possible proportion of the copper surface, which also keeps the conductor resistances small. With cladding on both sides, one or both copper layers can be patterned. A copper layer is preferably composed of high-ductility copper (‘HD copper’).

The thickness of the fiberglass composite layer is preferably between 70 μm and 125 μm.

The thickness of the ductile metal layer is preferably between 18 μm and 70 μm.

It can also be preferred if the total thickness of the substrate is preferably between 70 μm and 140 μm.

It is also preferred if the thickness of the fiberglass composite layer and the thickness of the ductile metal layer are approximately the same. Identical thickness increases flexibility and reversed bending stability.

A light device is also preferred in which the at least one fiberglass composite layer is clad on both sides with one copper layer respectively, as this produces particularly good shape retention. It is then particularly preferred if the copper layers are connected by means of at least one plated through-hole, because this firstly results in a functional double-layer board and secondly the plated through-hole can increase the stability of the substrate.

For good electrical conductivity and easy plastic deformation, the plated through-hole is preferably fashioned as a metal plated through-hole.

For use under practical constraints, it is preferable if a minimum bending radius is less than 2 cm, in particular less than 1 cm, specifically less than 5 mm and particularly specifically approximately 4 mm.

To achieve flexible use and a long service life even for different uses, it is preferable if the light device or substrate thereof withstands multiple bending cycles without loss of function. The number of bending cycles is preferably at least 50, better at least 100 and better still at least 200.

To achieve varied possible uses, it is particularly preferable if the flexible light device is fashioned as a light strip, i.e. has a width which is far less than its length. A minimal ratio of length to width of 3:1 is preferable.

For problem-free arrangement of components while simultaneously keeping the construction depth low, it is preferable if a strip width of the light strip is between 5 mm and 40 mm.

The aforementioned substrate properties (e.g. layer arrangement, material composition, dimensioning, etc.) can also be viewed as properties of the endless intermediate product.

With the aid of exemplary embodiments, the invention will be described in greater schematic detail in the following figures. For greater clarity, identical or equivalent elements are labeled with the same reference characters.

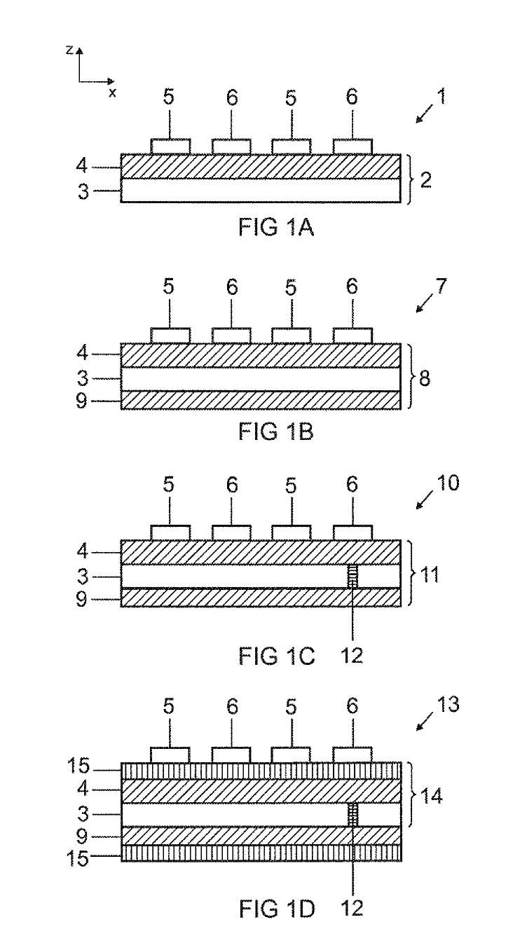

FIG. 1A shows as a sectional representation in side view a detail of a light strip according to a first embodiment;

FIG. 1B shows as a sectional representation in side view a detail of a light strip according to a second embodiment;

FIG. 1C shows as a sectional representation in side view a detail of a light strip according to a third embodiment;

FIG. 1D shows as a sectional representation in side view a detail of a light strip according to a fourth embodiment;

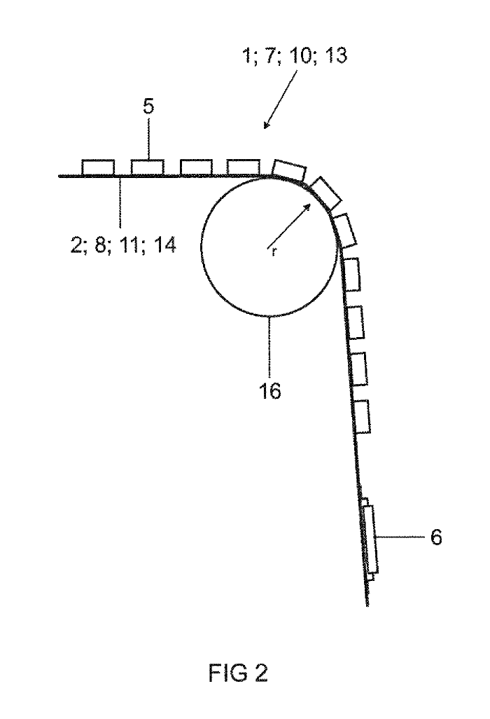

FIG. 2 shows as a sectional representation in side view a curved light strip;

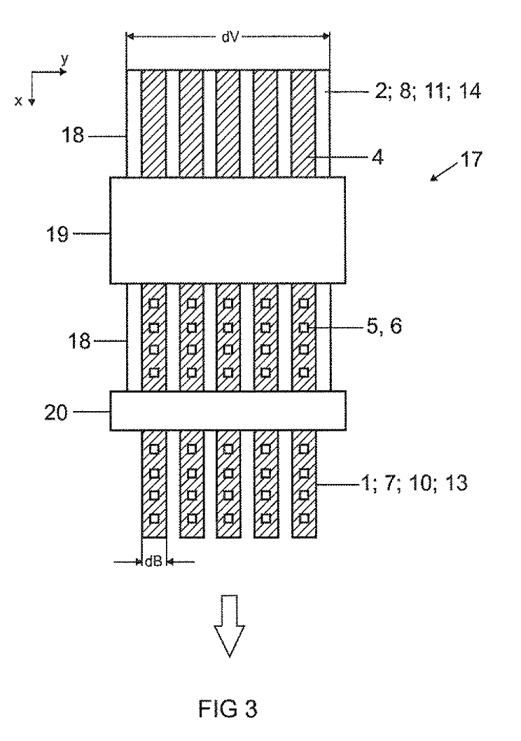

FIG. 3 shows in top view a production line for light strips and various stages in the production of light strips.

FIG. 1A shows as a sectional representation in side view a longitudinal section of a light strip 1 according to a first embodiment. The light strip 1 comprises a substrate 2 with a fiberglass/epoxy-resin composite layer 3 on which a copper layer 4 has been applied by means of hot-pressing. Functional components 5, 6 in the form of light-emitting diodes 5 and components 6 provided for operating the light-emitting diodes 5 such as driver modules, resistors, capacitors, etc. are mounted on the copper layer. The components 6 are fashioned as surface mounted devices (SMD).

The fiberglass/epoxy-resin composite layer 3 is composed of a mixture of 35% fiberglass and 65% epoxy resin, which exhibits a lower tendency to crack than a 1:1 mixture of these components. The fiberglass/epoxy-resin composite has a typical water absorption of 0.3%, a tracking resistance with a CTI (“comparative tracking index”) value of approx. 200, a minimum bending radius of approx. 4 mm and a reversed bending stability of 50 to 200 bending cycles before material failure. The thickness of the fiberglass/epoxy-resin composite layer 3 in the z dimension is preferably between 70 μm and 125 μm, here 70 μm.

The copper layer 4 consists of high-ductility copper of preferably between 18 μm and 70 μm, here 70 μm, in thickness. Increased flexibility and reversed bending stability are achieved by virtue of the fact that the fiberglass/epoxy-resin composite layer 3 and the copper layer 4 are of the same thickness (in the z dimension). For wiring the functional components 5, 6, the copper layer is patterned over its thickness for the insertion of conductor tracks. The flexibility and reversed bending stability are somewhat reduced by this, but due to the large copper surfaces remaining continue to be far improved. In order to keep the loss of volume of the copper layer 4 low, trenches inserted for patterning are fashioned as thinly as possible.

The substrate 3 can be used as an ‘endless’ base laminate for flexible light applications, in particular LED applications, with low water absorption and increased tracking resistance. By comparison, the use of the fiberglass/epoxy-resin composite layer 3 yields the advantages that production of the substrate 2 can be carried out at lower temperatures and thus in a more energy-saving manner than for polyamide or polyester. Also, the fiberglass/epoxy-resin composite layer 3 is more readily recyclable. The width of the substrate along the y dimension is preferably between 5 mm and 40 mm.

FIG. 1B shows in a representation analogous to FIG. 1A a light strip 7 according to a second embodiment. In contrast to the first embodiment, the light strip is now additionally clad on its back with a copper layer 9 similar to the copper layer 4 on the front. In particular, the material and the thickness are identical to one another, i.e. preferably between 70 μm and 80 μm, here 70 μm, while a thickness of the fiberglass/epoxy-resin composite layer 3 is preferably between 40 μm and 70 μm, here 70 μm. The fiberglass/epoxy-resin composite layer 3 is consequently clad here on both sides and due to the two copper layers 4, 9 has a further increased reversed bending stability. The copper layer 9 on the back can also be patterned and even fitted (not shown), but in this exemplary embodiment serves merely for adjusting the deformation behavior of the light strip 7.

FIG. 1C shows in a representation analogous to FIG. 1A a light strip 10 according to a third embodiment. In contrast to the second embodiment, a metallic plated through-hole (‘via’) 12 is shown here by way of example. The plated through-hole 12 can be produced for example by filling a bushing through the fiberglass/epoxy-resin composite layer 3 with conductive paste or electroplating. This makes it possible to achieve firstly more complex wiring (routing complexity) and secondly even further increased reversed bending stability.

FIG. 1D shows in a representation analogous to FIG. 1A a light strip 13 according to a fourth embodiment. In contrast to the third embodiment, a flexible insulation layer 15 has now been applied externally to both copper layers 4, 9. The insulation layer 15 is produced by a flexible solder resist or a corresponding cover film made e.g. of polyamide or epoxy resin. In this way, in particular, corrosion protection is achieved and the CTI value and dielectric strength increased.

FIG. 2 shows as a sectional representation in side view a curved light strip 1; 7; 10; 13 according to one of the above exemplary embodiments which is fitted with light-emitting diodes 5 and a driver module 6. The light strip 1; 7; 10; 13 is bent around a bar 16 which has a radius r of 4 mm, which consequently corresponds to the bending radius of the curvature of the light strip 1; 7; 10; 13. The light strip 1; 7; 10; 13 is designed so as to be still fully functional at this curvature.

FIG. 3 shows in top view a production line 17 for light strips 1; 7; 10; 13 and various stages in the production of the light strips 1; 7; 10; 13. Firstly, an intermediate product 18 provided as an endless strip is inserted into an automatic placement machine 19. The intermediate product 19 has a substrate 2; 8; 11; 14 identical to that of the later light strips 1; 7; 10; 13, but with a larger width dV, which lies preferably between 300 mm and 400 mm. On the substrate 2; 8; 11; 14, multiple patterned copper layers 4 are shown applied in parallel, these corresponding to the copper layers 4 of the later light strips 1; 7; 10; 13. In the automatic placement machine 19, the copper layers 4 are fitted in one pass and passed on to a singularizing station 20. At the singularizing station 20, the light strips 1; 7; 10; 13 are singularized with their thickness dB from the equipped intermediate product 19 e.g. by means of cutting processes. A preferred length of a light strip 1; 7; 10; 13 is more than 40 cm, in particular more than 60 cm.

The present invention is of course not restricted to the exemplary embodiments shown.

For example, the layers can be composed of multiple individual layers or films.

In each case, multiple fiberglass/epoxy-resin composite layers can be stacked on top of one another with multiple metal layers in no restricted order.

The intermediate product can for example also be covered with a cladding over its entire surface.

### LIST OF REFERENCE CHARACTERS

1 Light strip
2 Substrate
3 Fiberglass/epoxy-resin composite layer
4 Copper layer
5 Light-emitting diode
6 Components
7 Light strip
8 Substrate
9 Copper layer
10 Light strip
11 Substrate
12 Plated through-hole
13 Light strip
14 Substrate
15 Insulation layer
16 Bar
17 Production line
18 Intermediate product
19 Automatic placement machine
20 Singularizing station
dB Width of the light strip
dV Width of the intermediate product
r Bending radius

1. A method for producing a flexible light strip comprising a substrate designed for bending and provided for fitting with light sources, the method comprising:
singularizing the light strip from an endless intermediate product; and
the endless intermediate product comprising at least one fiberglass composite layer.

2. The method as claimed in claim 2,
wherein, during the singularizing, multiple light strips are singularized from the endless intermediate product.

3. The method as claimed in claim 1,
wherein the at least one light strip is singularized bare from the endless intermediate product.

4. The method as claimed in claim 1,
wherein the at least one light strip is singularized pre-fitted from the endless intermediate product.

5. The method as claimed in claim 1,
wherein the endless intermediate product comprises at least one patterned copper cladding.

6. The method as claimed in claim 1,
wherein the method comprises, after the singularizing the light strip detaching at least one light strip.

7. The method as claimed in claim 1,
wherein the endless intermediate product has a width of between 100 mm and 400 mm.

8. The method as claimed in claim 1,
wherein a light strip has a strip width of between 5 mm and 40 mm.

9. The method as claimed in claim 1,
wherein a light strip has a length of at least 1 m.

10. A flexible light device which is produced using a method comprising:
singularizing the light strip from an endless intermediate product; and
the endless intermediate product comprising at least one fiberglass composite layer.

11. A flexible light device comprising:
a substrate designed for bending which is provided for fitting with light sources,
wherein the substrate is produced with at least one fiberglass composite layer and the light device is jointless.

12. The flexible light device as claimed in claim 11,
wherein the fiberglass composite layer has a fiberglass/resin compound with a fiberglass proportion of less than 50% and more than 30%.

13. The flexible light device as claimed in claim 11,
wherein the at least one fiberglass composite layer is clad with at least one copper layer.

14. The flexible light device as claimed in claim 11,
wherein the at least one fiberglass composite layer is clad with one copper layer on both sides, and the copper layers are connected by means of at least one plated through-hole.

15. The flexible light device as claimed in claim 13,
wherein a thickness of the fiberglass composite layer matches a thickness of a copper layer.

16. The method as claimed in claim 1,
wherein the light sources comprise light-emitting diodes.

17. The method as claimed in claim 9,
wherein a light strip has a length of between 1 m and 20 m.

18. The flexible light device as claimed in claim 10, comprising:
a substrate designed for bending which is provided for fitting with light sources, wherein the substrate is produced with at least one fiberglass composite layer and the light device is jointless.

19. The flexible light device as claimed in claim 11,
wherein the fiberglass composite layer has a fiberglass/resin compound with a fiberglass proportion of between 30% and 45%.

20. The flexible light device as claimed in claim 19,
wherein the fiberglass composite layer has a fiberglass/resin compound with a fiberglass proportion of 35%.
